(19) United States
(12) Patent Application Publication
(10) Pub. No.: US 2014/0098472 A1
(43) Pub. Date: Apr. 10, 2014

(54) GLASS ENCLOSURE BODY HAVING MECHANICAL RESISTANCE TO IMPACT DAMAGE

(71) Applicant: Corning Incorporated, Corning, NY (US)

(72) Inventor: Bin Zhang, Penfield, NY (US)

(21) Appl. No.: 13/832,769

(22) Filed: Mar. 15, 2013

Related U.S. Application Data
(60) Provisional application No. 61/709,390, filed on Oct. 4, 2012.

(51) Int. Cl. H05K 5/02; H05K 5/03

(52) U.S. Cl. CPC H05K 5/02; H05K 5/03
USPC 361/679.01; 312/223.1

(57) ABSTRACT

An enclosure for a portable electronic device includes a glass sleeve having an oblong cross-sectional profile and a wall defining a cavity for an electronic insert. The wall comprises a first wall segment with a first thickness and a local radius or curvature of 10 mm or less and a second wall segment with a second thickness, where the first thickness is 20 to 50% greater than the first thickness.

### CROSS REFERENCE TO RELATED APPLICATIONS

This application claims the benefit of priority under 35 U.S.C. §119 of U.S. Provisional Application Ser. No. 61/709,390 filed on Oct. 4, 2012, the content of which is relied upon and incorporated herein by reference in its entirety.

### FIELD

The present disclosure relates to enclosures for portable electronic devices such as media players, smart phones, and the like.

### BACKGROUND

Glass has been used to cover the front surfaces of portable electronic devices. Electronic device manufacturers are now desiring that glass is also used to cover the side and back surfaces of portable electronic devices. For example, U.S. Patent Publication No. 2012/0069517 (“Prest et al.) discloses a portable computing device whose enclosure includes a main body formed from a glass tube. Prest et al. discloses that such an enclosure will permit wireless communication therethrough. Users of portable electronic devices tend to walk around carrying their portable electronic devices with them, which means that the likelihood of dropping these devices on hard surfaces cannot be ignored. Thus for a glass enclosure such as described in Prest et al. to be of practical use in portable electronic devices, the glass enclosure will need to be able to resist impact damage not just at the front, but at the back and sides.

### SUMMARY

The present disclosure describes portable electronic devices and enclosures for portable electronic devices having a glass enclosure body as a major component, where the glass enclosure body has improved mechanical resistance to impact damage.

In particular embodiments, the present disclosure provides an enclosure for a portable electronic device including a glass sleeve having a wall defining a cavity for an electronic insert, where the glass sleeve has an oblong cross-sectional profile, the wall includes a first wall segment with a first thickness and a local radius of curvature of 10 mm or less and a second wall segment with a second thickness, and the first thickness is 20 to 50% greater than the second thickness.

In particular embodiments, the present disclosure provides an enclosure for a portable electronic device including a glass sleeve having a wall defining a cavity for an electronic insert, where the cavity has an oblong cross-sectional profile, the wall includes a first wall segment with a first thickness and a local radius of curvature of 10 mm or less and a second wall segment with a second thickness, and the first thickness is 20 to 50% greater than the second thickness.

In particular embodiments, the present disclosure provides an enclosure for a portable electronic device including a glass sleeve having a wall defining a cavity for an electronic insert, where the glass sleeve has an oblong cross-sectional profile, the wall includes a first wall segment with a first thickness and a local radius of curvature of 10 mm or less and a second wall segment with a second thickness, and the first thickness is 20 to 50% greater than the second thickness. The enclosure also includes a pair of end caps for mounting at opposite ends of the glass sleeve, where each end cap has a tensile modulus greater than 40 MPa.

In particular embodiments, the present disclosure provides an enclosure for a portable electronic device including a glass sleeve having a wall defining a cavity for an electronic insert, where a surface compression layer is formed in the wall, the surface compression layer has a compressive stress greater than 700 MPa and a depth of compressive stress layer greater than 29 μm, and the wall includes at least one wall segment with a local radius of curvature of 10 mm or less.

In particular embodiments, the present disclosure provides a portable electronic device including an enclosure having a glass sleeve with a wall defining a cavity in which an electronic insert comprising electronic components of the portable electronic device is disposed, where the wall of the glass sleeve has a surface compression layer formed therein, the surface compression layer has a compressive stress greater than 700 MPa and a depth of compressive stress layer greater than 29 μm, the wall includes a first wall segment with a first thickness and a local radius of curvature of 10 mm or less and a second wall segment with a second thickness, and the first thickness is 20 to 50% greater than the second thickness.

In particular embodiments, the present disclosure provides a portable electronic device including an enclosure having a glass sleeve with a wall defining a cavity in which an electronic insert comprising electronic components of the portable electronic device is disposed, where the cavity and electronic insert each have an oblong cross-sectional profile, the wall includes a first wall segment with a first thickness and a local radius of curvature of 10 mm or less and a second wall segment with a second thickness, and the first thickness is 20 to 50% greater than the second thickness.

It is to be understood that both the foregoing general description and the following detailed description are exemplary of the invention and are intended to provide an overview or framework for understanding the nature and character of the invention as it is claimed. The accompanying drawings are included to provide a further understanding of the invention and are incorporated in and constitute a part of this specification. The drawings illustrate various embodiments of the invention and together with the description serve to explain the principles and operation of the invention.

### BRIEF DESCRIPTION OF THE DRAWINGS

The following is a description of the figures in the accompanying drawings. The figures are not necessarily to scale, and certain features and certain views of the figures may be shown exaggerated in scale or in schematic in the interest of clarity and conciseness.

FIG. 1 is an exploded view of an enclosure for a portable electronic device.

FIG. 2 is an end view of a glass sleeve.

FIG. 3 is an end view of a glass sleeve with thick side walls.

FIG. 4 is a cross-sectional view of a glass sleeve showing surface compression layer.

FIG. 5 is a portable electronic device.

FIG. 6 is a cross-sectional view a portable electronic device.

FIG. 7 is a plot of showing the effect of radius of curvature on maximum tensile stress in a glass sleeve under a drop simulation.

FIG. 8 is a plot showing the effect of wall thickness on maximum tensile stress in a glass sleeve under a drop simulation.

FIG. 9 is a plot showing the effect of insert material, sleeve geometry, and wall thickness on maximum tensile stress in a glass sleeve under a drop simulation.

FIG. 10 is a plot showing the effect of end cap material on maximum tensile stress in a glass sleeve under a drop simulation.

FIG. 11 is a plot showing the effect of wall thickness on impact energy at failure in a glass sleeve in an actual experiment.

### DETAILED DESCRIPTION

In the following detailed description, numerous specific details may be set forth in order to provide a thorough understanding of embodiments of the invention. However, it will be clear to one skilled in the art when embodiments of the invention may be practiced without some or all of these specific details. In other instances, well-known features or processes may not be described in detail so as not to unnecessarily obscure the invention. In addition, like or identical reference numerals may be used to identify common or similar elements.

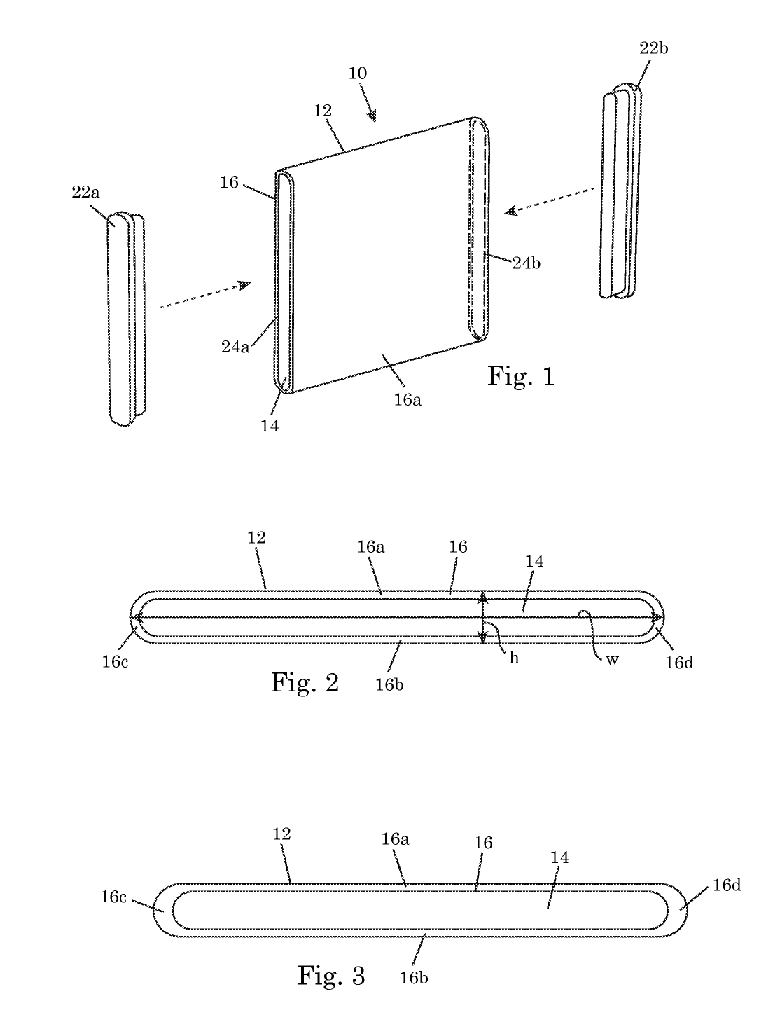

FIG. 1 shows an enclosure 10 for a portable electronic device. The enclosure 10 includes a glass enclosure body 12, which is in the form of a glass sleeve. The glass sleeve 12 has a cavity 14 appropriately sized to receive an electronic insert, which is an assembly of electronic device components. The glass sleeve 12 is made of a wall 16. In FIG. 2, the wall 16 has a front (or top) wall segment 16a, a back (or bottom) wall segment 16b, and side wall segments 16c, 16d. The front and back wall segments 16a, 16b are opposed and spaced apart, and the side wall segments 16c, 16d are opposed and spaced apart, with the side wall segments 16c, 16d extending between the front and back wall segments 16a, 16b and the spacing between the front and back wall segments 16a, 16b being smaller than the spacing between the side wall segments 16c, 16d. The space between the wall segments 16a, 16b, 16c, 16d define the cavity 14. In one embodiment, the glass sleeve 12 is seamless, which means that there are no physical seams or joints between the wall segments 16a, 16b, 16c, 16d and that the wall 16 is monolithic. The glass sleeve 12 may be made from a glass tube. Where the glass sleeve 12 is seamless, the glass tube will also be seamless.

The glass sleeve 12 has an oblong cross-sectional profile, where “oblong” means elongated. An example of an oblong cross-sectional profile is shown in FIG. 2, but the glass sleeve 12 is not limited to the particular oblong cross-sectional profile shown in FIG. 2. The oblong cross-sectional profile is characterized by a height h, which is the shortest distance between the front and back wall segments 16a, 16b, and a width w, which is the shortest distance between the side wall segments 16c, 16d. The side wall segments 16c, 16d may be flat walls or curved walls. The front and back wall segments 16a, 16b may also be flat walls or curved walls or may be generally flat walls incorporating some contours. Typically, the front wall segment 16a will be flat. The back wall segment 16 may incorporate contours that may facilitate handling of the glass sleeve. In one embodiment, the cavity 14 of the glass sleeve 12 also has an oblong cross-sectional profile. The oblong cross-sectional shape of the cavity 14 may the same as or different from the oblong cross-sectional shape of the glass sleeve 12.

In a specific embodiment, the side wall segments 16c, 16d are curved walls. The curve profile of the curved walls may be simple or compound. Each curve profile can be considered to have a local radius of curvature, which may be constant or changing along the length of the curve. As will be demonstrated later, the local radius of curvature of the curved profile of each side wall segment 16c, 16d has an effect on the maximum tensile stress induced in the glass sleeve 12 when the glass sleeve 12 impacts a rigid body, such as might occur under real use of the glass sleeve 12. In particular, it has been found that the smaller the local radii of curvature of the side wall segments 16c, 16d, the lower the induced maximum tensile stress in the glass sleeve 12 may be upon impact. Along these lines, to improve the mechanical resistance of the glass sleeve 12 to impact damage, the local radius of curvature of each side wall segment 16c, 16d is preferably 10 mm or less. In another embodiment, the local radius of curvature of each side wall segment 16c, 16d is preferably 6 mm or less. In yet another embodiment, the local radius of curvature of each side wall segment 16c, 16d is preferably 4 mm or less.

In one embodiment, the wall 16 of the glass sleeve 12 has a thickness less than 1.5 mm, preferably in a range from 0.8 mm to 1.2 mm. In one embodiment, local wall thickness variations are used to reinforce selected areas of the glass sleeve 12 that are vulnerable to fracture propagation. It has been found that this local wall thickness variation together with small local radius of curvature, e.g., at the side wall segments 16c, 16d, can greatly reduce the maximum tensile stress within the glass sleeve 12 when the glass sleeve 12 impacts a rigid body. An example of local thickness variation is shown in FIG. 3, where the side wall segments 16c, 16d are thicker than the front and back wall segments 16a, 16b. In one embodiment, the thickness of each side wall segment 16c, 16d is 20 to 50% higher than the thickness of each front and back wall segment 16a, 16b. What is considered as the thickness of the wall segments does not include the transition regions between each side wall segment 16c, 16d and the adjacent front and back wall segments 16a, 16b where the wall thickness will vary from the higher thickness of the side wall segment to the lower thickness of the adjacent top or back wall segment. Local wall thickness variation means that while the side wall segments 16c, 16d are made thick, the front wall segment 16a can be made thin enough to allow viewing of the display without optical issues like parallax.

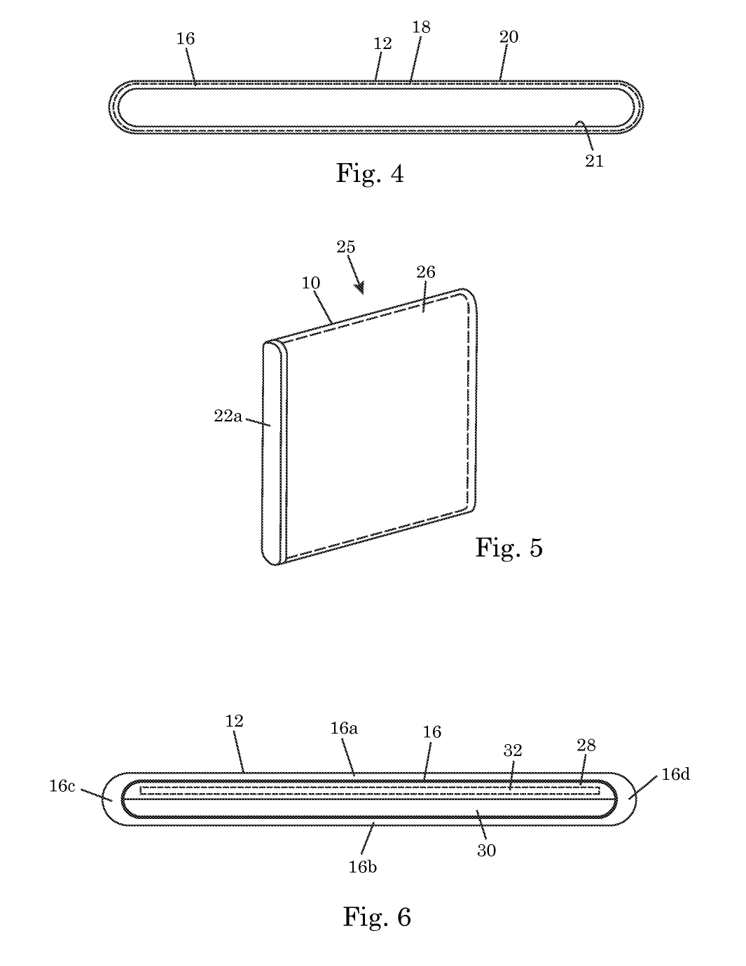

To further improve the resistance of the glass sleeve 12 to impact damage, the glass sleeve 12 has a surface compression layer 18, as shown in FIG. 4, which extends from the outer surface 20 of the glass sleeve wall 16 to some depth within the thickness of the wall 16. In one embodiment, the compressive stress in the surface compressive layer 18 is greater than 700 MPa. In another embodiment, the compressive stress may range from 800 MPa to 1,000 MPa. In one embodiment, the depth of the surface compression layer 18, measured from the outer surface 20 of the wall 16 into the thickness of the wall 16, is preferably greater than 29 μm. In another embodiment, the depth of the surface compression layer 18 preferably ranges from about 30 μm to 50 μm. In yet another embodiment, the depth of the surface compression layer 18 preferably ranges from about 40 μm to 60 μm. The surface compression layer can be formed in the wall 16 of the glass sleeve 12 by chemical tempering, such as ion-exchange, or thermal tempering. The preferred combinations of compressive stress and depth of the surface compression layer can be achieved by selection of glass composition and selection and control of tempering parameters.

In one embodiment, the glass sleeve 12 is made from a glass composition that can be chemically tempered by ion-exchange. Typically, these ion-exchangeable glasses contain relatively small alkali metal or alkaline-earth metal ions that can be exchanged for relatively large alkali or alkaline-earth metal ions. These ion-exchangeable glasses can be alkali-aluminosilicate glasses or alkali-aluminoborosilicate glasses. Examples of ion-exchangeable glasses can be found in the patent literature, e.g., U.S. Pat. No. 7,666,511 (Ellison et al; 20 Nov. 2008), U.S. Pat. No. 4,483,700 (Forker, Jr. et al.; 20 Nov. 1984), and U.S. Pat. No. 5,674,790 (Araujo; 7 Oct. 1997), all incorporated by reference in their entireties, and are also available from Corning Incorporated under the trade name GORILLA® glass.

The outer surface 20 of the glass sleeve 12 may be coated with one or more coatings, such as an anti-reflection coating and/or anti-smudge coating. Portions of the glass sleeve 12 may also be made semi-transparent or opaque via deposition of suitable coating materials, typically on the inner surface 21 of the glass sleeve 12.

In FIG. 1, the enclosure 10 further includes end caps 22a, 22b, which are shaped for mounting at the opposing, open ends 24a, 24b, respectively, of the glass sleeve 12 such that they engage the wall 16 of the glass sleeve 12 and seal or close the cavity 14. The seal does not need to be hermetic. The end caps 22a, 22b may be designed to be mounted at the ends 24a, 24b of the glass sleeve 12 using any suitable means, such as snap-fitting, gluing, and the like. The end caps 22a, 22b may be removable to allow an electronic insert to be arranged in the cavity 14 and to allow subsequent access to the electronic insert after it has been arranged in the cavity 14. The end caps 22a, 22b can be made of various materials, such as plastics and metals. In one embodiment, the higher the tensile modulus or stiffness of the end caps 22a, 22b, the better the ability of the ends 24a, 24b of the glass sleeve 12 to resist damage upon impact with a rigid body. In one embodiment, the end caps 22a, 22b are made of a material having a tensile modulus greater than 40 MPa. Examples of suitable materials for the end caps 22a, 22b are, but not limited to, DELRIN® acetal resins from Dupont and aluminum.

FIG. 5 shows a portable electronic device 25 including an electronic insert 26 inside the enclosure 10. The electronic insert 26 was disposed inside the cavity (14 in FIG. 1) of the glass sleeve 12, and the end caps 22a, 22b (in FIG. 1) were mounted at the open ends of the glass sleeve 12. In one embodiment, as shown in FIG. 6, the overall shape of the electronic insert 26 is such that the electronic insert 26 completely fills the cavity 14. This means that where the cavity 14 of the glass sleeve 12 has an oblong cross-sectional profile, the electronic insert 26 would also have an oblong cross-sectional profile approximately matching that of the cavity. In other embodiments, the electronic insert 26 may not completely fill the cavity 14, and there may be gaps between the electronic insert 26 and the inner surface of the glass sleeve 12. In such case, if desired, filler material may be added to the cavity 14 to fill the gaps. The enclosure 10 is considered to have a soft fill if the electronic insert 26 does not completely fill up the cavity 14 and a stiff fill if the electronic insert 26, along with any filler material, completely fills up the cavity 14. Whether the fill of the cavity 14 is soft or stiff may affect the location of maximum tensile stress in the glass sleeve 12 upon impact with a rigid body.

The portable electronic device 25 may be a smart phone, media player, or other handheld device. As shown in FIG. 6, the electronic insert 26 may include a user interface subassembly 28 and an operations subassembly 30. The user interface subassembly 28 may include various elements to allow user interaction with the portable electronic device 25, e.g., a display or an input device, such as a keyboard, touch pad, touch screen, joystick, trackball, buttons, switches, and the like. The operations subassembly 30 may include various elements to perform operations, e.g., a microprocessor, memory, hard drive, battery, input/output connectors, wireless transmission module, antenna, and the like. The various elements of the user interface subassembly 28 and operations subassembly 30 may be mounted on one or more supports, which may be made of suitable materials such as plastics or metals or may be printed boards. When the user interface subassembly 28 includes a display, whose location is indicated approximately at 32, the front wall segment 16a of the glass sleeve 12 may allow viewing of and interaction with the display. In such a case, both the display and front wall segment 16a, or the portion of the front wall segment 16a overlying the display 32, is preferably flat.

### EXAMPLE 1

A test portable electronic device was devised for various studies. The test portable electronic device included a solid insert disposed within the cavity of a seamless glass sleeve, with end caps mounted at the ends of the glass sleeve to contain the solid insert within the cavity. The solid insert represented an electronic insert. The glass sleeve had a basic oblong profile consisting of parallel top and wall segments and semi-circular side wall segments.

### EXAMPLE 2

A drop simulation consisted of calculating the instantaneous stress developed in a glass sleeve upon impact with a flat rigid surface with an energy corresponding to a 1 m height drop. The rigid surface was granite.

### EXAMPLE 3

The impact of drop orientation on stress within the glass sleeve of a test portable device as described in Example 1 was studied using a drop simulation as described in Example 2. Various orientations of the test portable device that reflect the cases occurring in a use environment were used in the drop simulation. Depending on the orientation of the test portable electronic device, the initial impact changed, as well as the trajectory resulting from the impact, e.g., bouncing or secondary impacts. The simulation results showed that the drop on the curved side walls of the glass sleeve resulted in much higher stress in the glass sleeve than the drop on the end corners of the glass sleeve. The end corners of the glass sleeve were protected by the end caps.

### EXAMPLE 4

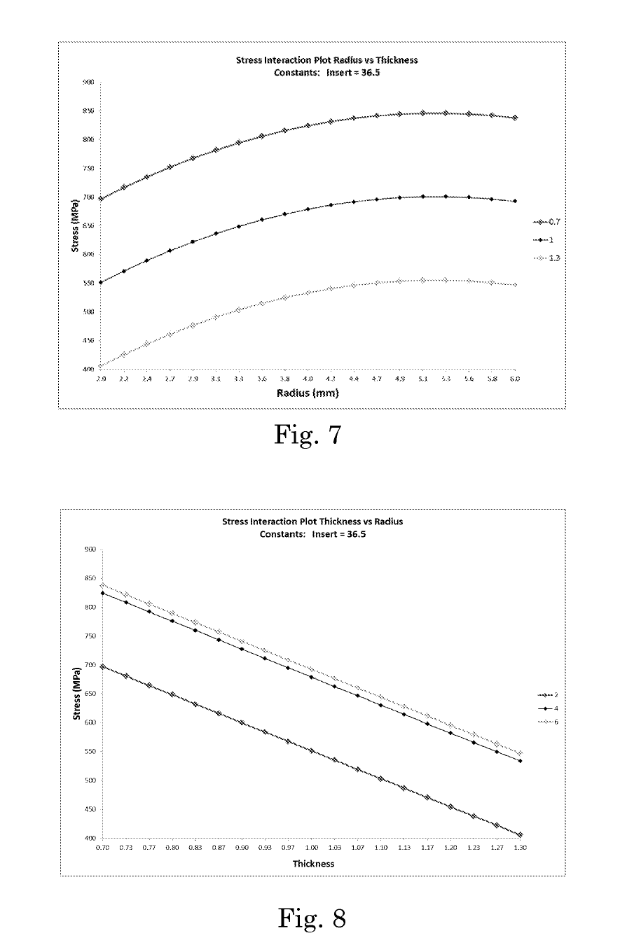

The impact of sleeve geometry on stress within the glass sleeve of a test portable device as described in Example 1 was studied using a drop simulation as described in Example 2. The test portable device as described in Example 1 was used in the study. The drop orientation was limited to a side drop in view of Example 3. The glass sleeve had a uniform wall thickness, which was selected from 0.7 mm, 1 mm, and 1.3 mm. The relationship between the maximum tensile stress within the glass sleeve as a function of the radius of curvature of the side wall segments is shown in FIG. 7. The results show that the lower the radius of curvature, the lower the maximum tensile stress within the glass sleeve from the side drop of the test portable device.

### EXAMPLE 5

The impact of wall thickness on stress within the glass sleeve of a test portable device as described in Example 1 was studied using a drop simulation as described in Example 2. The test portable device as described in Example 1 was used in the study. The drop orientation was limited to a side drop in view of Example 3. Glass sleeve thicknesses ranged from 0.7 mm to 1.3 mm. The relationship between the maximum tensile stress within the glass sleeve as a function of wall thickness of the glass sleeve is shown in FIG. 8. The results show that the higher the wall thickness, the lower the maximum tensile stress within the glass sleeve from the side drop of the test portable device.

### EXAMPLE 6

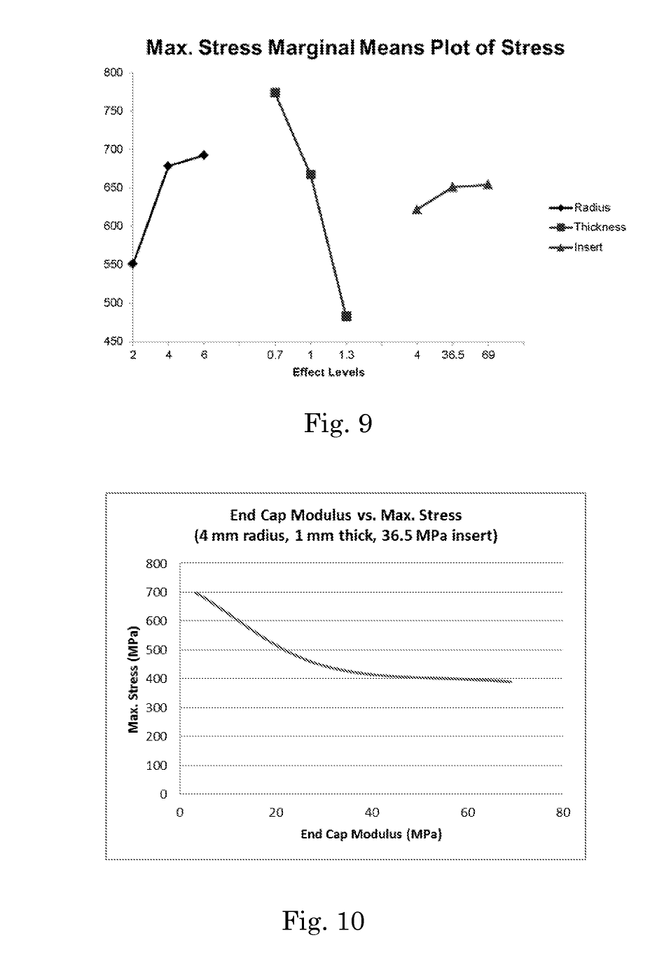

The impact of insert material, sleeve geometry, and glass sleeve wall thickness on the stress within the glass sleeve of a test portable device as described in Example 1 was studied using a drop simulation as described in Example 2. The test portable device as described in Example 1 was used in the study. The drop orientation was limited to a side drop in view of Example 3. The results are shown in FIG. 9 in terms of stress versus effect levels. The results show that insert modulus plays a trivial role in glass stress because the highest glass stress always occurred at the ends of the glass sleeve, which is mostly controlled by the interaction between the glass sleeve and the end caps. The weight of the insert will be more important than the stiffness or modulus of the insert at least in the side drop.

### EXAMPLE 7

The impact of end cap material on the stress within the glass sleeve of a test portable device as described in Example 1 was studied using a drop simulation as described in Example 2. The test portable device as described in Example 1 was used in the study. The drop orientation was limited to a side drop in view of Example 3. The results are shown in FIG. 10 in terms of stress versus end cap modulus. The results show that as the tensile modulus (or stiffness) of the end cap increases, the stress in the glass decreases.

### EXAMPLE 8

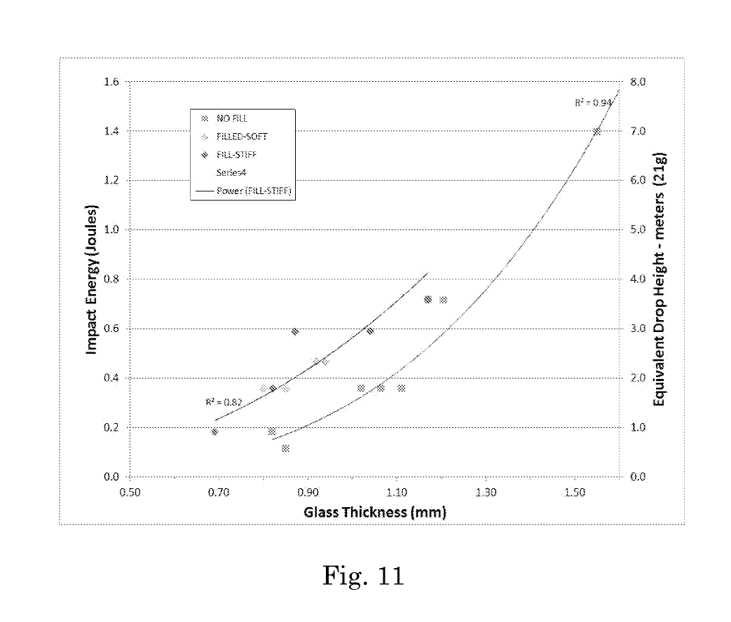

FIG. 11 is a plot showing impact energy at failure versus wall thickness of glass sleeve, where the thickness of the glass sleeve is uniform. A test portable device was prepared as described in Example 1. For the plot shown in FIG. 11, impact energy was applied to the test portable device using a pendulum and until the glass sleeve of the test portable device failed. Experimental data were collected for an empty glass sleeve (no fill), a glass sleeve containing an insert having a rectangular profile (soft fill), and a glass sleeve containing an insert having an oblong cross-sectional profile (stiff fill), where the glass sleeve had an oblong cross-sectional profile in all cases. The drop height corresponding to the impact energy is also shown in FIG. 11. The plot of FIG. 11 shows that the impact energy at failure increases as wall thickness of the glass sleeve increases. The shape of the insert does not seem to have much effect on the amount of impact energy required to cause failure. However, whether the glass sleeve is empty or contains an insert does have an effect on the amount of impact energy required to cause failure, with the latter requiring more impact energy.

From the examples above, the thicker the wall of the glass sleeve, the higher the mechanical resistance of the glass sleeve to failure upon impact with a rigid body may be. However, this has to be balanced with weight and space constraints, which would be specified by the electronic device manufacturers. Portable electronic devices are typically desirably required to be small and lightweight. A combination of local radius of curvature at the side wall segments and local variations in wall thickness of the glass sleeve together with enhanced glass properties can be used to achieve improved mechanical resistance of the glass sleeve while keeping within the desired weight and space constraints.

While the invention has been described with respect to a limited number of embodiments, those skilled in the art, having benefit of this disclosure, will appreciate that other embodiments can be devised which do not depart from the scope of the invention as disclosed herein. Accordingly, the scope of the invention should be limited only by the attached claims.

1. An enclosure for a portable electronic device, comprising:
a glass sleeve having an oblong cross-sectional profile and a wall defining a cavity for an electronic insert, the wall comprising a first wall segment with a first thickness and a local radius of curvature of 10 mm or less and a second wall segment with a second thickness, the first thickness being 20 to 50% greater than the second thickness.

2. An enclosure for a portable electronic device, comprising:
a glass sleeve having a wall defining a cavity for an electronic insert, the cavity having an oblong cross-sectional profile, the wall comprising a first wall segment with a first thickness and a local radius of curvature of 10 mm or less and a second wall segment with a second thickness, the first thickness being 20 to 50% greater than the second thickness.

3. An enclosure for a portable electronic device, comprising:
a glass sleeve having an oblong cross-sectional profile and a wall defining a cavity for an electronic insert, the wall comprising a first wall segment with a first thickness and a local radius of curvature of 10 mm or less and a second wall segment with a second thickness, the first thickness being 20 to 50% greater than the second thickness; and
a pair of end caps mounted at opposite ends of the glass sleeve, each end cap having a tensile modulus greater than 40 MPa.

4. An enclosure for a portable electronic device, comprising:
a seamless glass sleeve having a wall defining a cavity for an electronic insert and a surface compression layer formed in the wall,
the surface compression layer having a compressive stress greater than 700 MPa and a depth of compressive stress layer greater than 29 μm,
the wall comprising at least one wall segment with a local radius of curvature of 10 mm or less.

5. A portable electronic device, comprising:
an enclosure comprising a glass sleeve having a wall defining a cavity in which an electronic insert comprising electronic components of the portable electronic device is disposed,
the wall having a surface compression layer formed therein, the surface compression layer having a compressive stress greater than 700 MPa and a depth of compressive stress layer greater than 29 μm,
the wall comprising at least one wall segment with a local radius of curvature of 10 mm or less.

6. A portable electronic device, comprising:
an enclosure comprising a glass sleeve having a wall defining a cavity in which an electronic insert comprising electronic components of the portable electronic device is disposed,
the cavity and electronic insert each having an oblong cross-sectional profile,
the wall comprising a first wall segment with a first thickness and a local radius of curvature of 10 mm or less and a second wall segment with a second thickness,
the first thickness being 20 to 50% greater than the second thickness.
